(19) United States
(12) Patent Application Publication
(10) Pub. No.: US 2018/0261473 A1
(43) Pub. Date: Sep. 13, 2018

(54) APPARATUS AND METHOD ESPECIALLY FOR DEGASSING OF SUBSTRATES

(71) Applicant: EVATEC AG, Trubbach (CH)

(72) Inventors: Jürgen WEICHART, Balzers (LI); Fabio Antonio RAVELLI, Buchs (CH)

(73) Assignee: EVATEC AG, Trübbach (CH)

(21) Appl. No.: 15/534,267

(22) PCT Filed: Dec. 9, 2015
(86) PCT No.: PCT/EP2015/079074

§ 371 Date: Jun. 8, 2017

Related U.S. Application Data
(60) Provisional application No. 62/090,537, filed on Dec. 11, 2014.

(51) Int. Cl. H01L 21/67; H01L 21/687; C23C 16/44

(52) U.S. Cl. CPC H01L 21/6719; H01L 21/68714; C23C 16/4401; C23C 16/4411; H01L 21/67115

(57) ABSTRACT

A heater or cooler vacuum chamber for degassing includes an enclosure and within the enclosure a controllably heatable or coolable pocket. Within the pocket is a workpiece holder and a gas feedline discharging the pocket. The inner surface of the pocket surrounds the workpiece in a closely spaced manner. The two halves forming the pocket may be controllably separate so as to allow a gas flow connection which establishes a negligible gas flow restriction to the remainder of the enclosure.

### BACKGROUND OF THE INVENTION

Degassing means the removal of gases, especially (i) gases from evaporated liquids like water or (ii) vapours that result from sublimating materials adhering to surfaces or (iii), in vacuum technology, substances that are outgassing from (bulk) material as soon as the surrounding pressure falls below its vapour pressure. In certain vacuum treatment processes, especially vacuum sputter coating processes degassing is an important process step, since residual gases may result in deteriorated adhesion of deposited layers or unwanted by-products in the deposits.

One differentiates between atmospheric and sub-atmospheric degassing. As the term suggests, sub atmospheric degassing takes place in an environment where the surrounding pressure can be lowered below atmospheric pressure.

It is known that degassing can be accelerated by heating the substrates thus enhancing the outgassing rate. This method may however have its limits for certain types of materials (e.g. plastics) or where the result of previous process steps could be (negatively) affected, such as melting solder bumps, warping or increased unwanted diffusion processes. Pump capacities may be improved to more quickly remove unwanted vapours and gases. However the physics of the outgassing process itself remains the main limiting factor. In order to avoid that in an inline processing system with a sequence of defined process steps the degassing of a single substrate becomes the determining factor for the throughput, degassing is sometimes organized in batches. In other words, a plurality of substrates is being exposed jointly to an environment that assists the degassing. However, such a possibility does not always exist for process reasons or because no space exists for such a device in a processing environment. A batch degasser as part of a single wafer process flow may be a demanding task for substrate scheduling and may slow down the process flow.

Consequently, there is a need for an apparatus for degassing single substrates individually, hereinafter called “degasser”, for (highly) outgassing substrates.

### TECHNICAL BACKGROUND

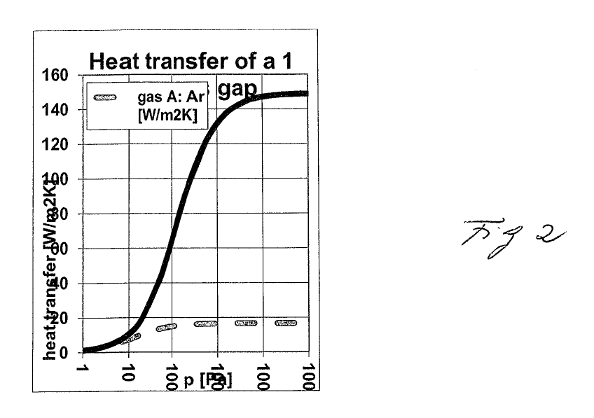

Several concepts for heating and degassing substrates are available. The 3 main methods are:
1. Heating by radiation, i.e. lamps or hot radiating surfaces
2. Heating by gas conduction at an elevated pressure (>10 mbar, see FIG. 2)
3. Heating by back side gas conduction with a substrate clamped to a hot chuck, the clamping may be a mechanical edge clamp or an ESC (electrostatic chuck)

### DRAWBACKS IN PRIOR ART

The disadvantage of heating by radiation is that while the radiation source can be turned off (lamp) or shielded (radiating surface), the temperature rise will continue depending on the thermal capacity and radiation absorption of the substrate and the thermal inertia of the heating system. This is especially critical for substrates with polymer layers which may be destroyed if a certain temperature is exceeded.

The disadvantage of heating by conduction with a substrate clamped to a hot chuck is that the heat up rate is rather low. In a process as known in the art a substrate is clamped to the surface of a hot chuck and gas is being introduced in the gap between chuck and substrate to enhance the heat transfer. However, in many cases the required gas conductivity cannot be reached, especially when a mechanical edge clamp is used. The mechanical edge clamp also bears the risk that after the heat and outgassing step the substrate sticks to the chuck. This is especially the case with laminated substrates like silicon on glass. A further disadvantage is that some substrates are not allowed to be touched on their back side in order to avoid contamination.

Heating by gas conduction has been proposed in several publications. Inter alia this has been described in U.S. Pat. No. 6,002,109 (Mattson) and U.S. Pat. No. 6,172,337 (Mattson). This application is targeting very high temperatures and includes a quartz ring as an insulator to protect against radiation losses.

U.S. Pat. No. 6,929,774B2, U.S. Pat. No. 6,423,947 and US 20110114623A1 include a cooling position, where the substrate is able to travel between a heating and cooling position. Whereas this may be a compact arrangement, the disadvantage here is that in the degasser a higher volume for the conducting gas is required and that there are thermal losses from the hot to the cold plate by radiation.

As will be addressed below, the heat transfer conditions, which are addressed above with an eye specifically on degassing are applicable also to cooling of a respective workpiece. The term “workpiece” shall hereinafter be understood as a material piece or as a substrate (terms used interchangeably), that is subject to a treatment by means of the chamber or apparatus of the present invention and/or by the process according to the invention. The appearance of the workpiece may vary and shall not be limiting the generality of the invention, but is preferably a plate-shaped workpiece, such as a semiconductor, ceramic or glass wafer.

Further and with respect to the conditions addressed above, it makes no difference whether a single distinct workpiece is to be thermally treated or, simultaneously, more than one such distinct workpiece, i.e. more than one distinct substrate.

Thus, it is an object of the present invention to provide an alternative heater and/or cooler chamber for at least one workpiece.

There is proposed, according to the present invention, a heater and/or cooler vacuum chamber for at least one workpiece, preferably a single workpiece, thereby especially a degasser chamber.

The chamber comprises an enclosure enclosing an enclosure volume i.e. a hollow space within the enclosure. Within the enclosure volume there is provided a controllably heatable and/or coolable pocket which encloses a pocket volume, i.e. a hollow space within the pocket.

There is provided in the pocket volume a workpiece holder. A gas feedline discharges in the pocket volume.

In the enclosure, i.e. in the enclosure wall, there is provided a port from the environment of the enclosure into the enclosure volume. Especially if the chamber according to the present invention is a degasser chamber, the addressed port is a pumping port i.e. is to be connected to a pump of a respective heater and/or cooler apparatus comprising the addressed chamber. Further there is provided at least one controllably openable and closable workpiece-handling opening into the enclosure, such as a gate valve, for introducing and removing a workpiece to be treated or having been treated respectively.

The inner surface of the pocket is tailored to surround the workpiece, arranged on the workpiece holder, in a closely spaced manner but distant from the workpiece. Thereby a minimal volume of the pocket volume is realised which surrounds the workpiece on the holder.

The pocket further comprises a controllably closable and openable gas flow connection from the pocket volume into the remainder of the enclosure volume. This gas flow connection represents, in open state, a negligible gas flow restriction.

Thus, opening the addressed gas flow connection results in an abrupt equalisation of gas pressure in the remainder of the enclosure volume and the pocket volume.

Especially with an eye on the chamber according to the invention being a degasser chamber, the two conflicting principles of degassing are thus taken into account: Heating up the workpiece is most efficient because the source of heat i.e. the pocket is spatially closely related to the workpiece to be heated. Nevertheless, the outgassing step is effected most efficiently because, while the gas flow connection is open, the workpiece becomes surrounded by a generous space. Such generous space, the remaining volume of the enclosure volume, allows for a high pumping profile. A low pumping profile would considerably decrease the efficiency of gas removal from the enclosures volume.

In one embodiment of the chamber according to the invention, the pocket comprises two mutually controllably joinable and separable parts. The parts are separable through the pocket volume. Thereby a very small gas flow restriction may be easily realised by widely separating these parts.

In one embodiment of the embodiment just addressed, the chamber is tailored to accommodate a plate shaped workpiece. The parts of the pocket are separable in a direction perpendicular to the extended surfaces of the plate shaped workpiece. In a further embodiment the parts are separable adjacent the periphery of the plate shaped workpiece.

More generically the workpiece on the workpiece holder is kept in a position substantially equally spaced from the addressed parts in the closed position of the pocket. In the open position of the pocket the respective distances to the parts are substantially larger compared to when the pocket is closed.

In the embodiment which comprises two mutually controllably joinable and separable parts, both these parts may comprise a heater and/or cooler. In one embodiment only one part comprises a heater and/or a cooler. Thus, only one part of the pocket is actively heating and/cooling the pocket volume. In a further embodiment, the heater is a two zone heater.

In an embodiment of the chamber as just addressed, i.e. the chamber at which only one of the parts comprises a heater and/or cooler this one part has a thermal mass, which is substantially smaller than the thermal mass of the other part.

Consequently the one part which is actively heated and/or cooled reaches a desired temperature quickly, whereas the other part acts as thermal reservoir which, once heated up or cooled down, may be exploited for subsequent heating or cooling workpieces applied to the pocket subsequently.

In an embodiment of the chamber according to the invention with two of the addressed parts the at least one workpiece on the workpiece holder is more distant from at least one of the parts, preferably from both of the parts, in open state than in closed state of the pocket.

Consequently the respective thermal state of the one or of both parts does influence the workpiece significantly more when the pocket is closed than when the pocket is open. This is particularly advantageous in combination with an embodiment in which one part has a high thermal mass and acts as a thermal storage or reservoir. By increasing the distance between the workpiece and such part when the pocket is opened, the substrate becomes thermally decoupled from that part i.e. from the reservoir.

In one embodiment of the chamber according to the invention, the pocket is substantially thermally decoupled from the enclosure. Therefore, a thermal flow is avoided between the pocket and the enclosure preferably in both states of the pocket, i.e. in open and in closed state.

In an embodiment of the chamber according to the invention, with a pocket having the addressed two parts, one part of the pocket is a part of the wall of the enclosure. Thus, for separating the two parts of the pocket it is only the other part, which is moved with respect to the enclosure.

In one embodiment of the chamber according to the present invention with a pocket with two parts separable and joinable as previously described, these parts are separable by at least 50 mm so as to realise the addressed minimum flow restriction.

In a further embodiment of the chamber according to the invention the ratio of the enclosure volume to the pocket volume is at least 10, even at least 30, even better at least 35. he pocket volume, even better at least 35 times larger. When the pocket is opened, the pressure in the small pocket volume will abruptly be lowered essentially to the prevailing pressure in the enclosure volume because of the volume ratios.

In an embodiment of the chamber according to the invention the enclosure comprises cooling means and/or heating means for the enclosure volume, in a further embodiment thereof a water cooling and/or heating arrangement. Thereby, the workpiece is cooled or respectively heated as soon as the pocket has been opened and with respect to the workpiece temperature during heating or cooling in the closed pocket.

In an embodiment of the chamber according the invention having a two part pocket at least one part of the pocket is movably linked to the enclosure by means of a bellow. The gas feed line is arranged within said bellow, towards and into the pocket. The bellow is gas-tight and separates ambient atmosphere from the atmosphere in the enclosure volume.

Any number of embodiments of the chamber according to the present invention, which were described, may be combined with the exception of embodiments, which are contradictory.

The present invention is further directed to a heater and/cooler apparatus, especially a degasser apparatus which comprises a chamber according to the present invention or a chamber according to at least one of the embodiments as outlined above. Such apparatus comprises a gas reservoir which is operationally connected to the gas feed line of the chamber and which contains at least one of Ar, N2, He. By feeding gas from the gas reservoir into the closed pocket of the chamber, heat transfer between the workpiece and the pocket is significantly improved.

In an embodiment of the apparatus a vacuum pump is operationally connected to the port of the chamber. In the case where the addressed chamber and the respective apparatus are degassing equipment gases which have been removed from the workpiece by heating in the closed pocket are removed from the enclosure by the vacuum pump once the pocket has been opened.

In the case the chamber and the apparatus are intended as cooling equipment, it may be desirable to remove gases from the enclosure before the pocket is closed and/or after the pocket is opened during a cooling process.

The present invention is further directed to a method of manufacturing at least one thermally treated workpiece, especially a single workpiece and especially at least one degassed workpiece.

The method according to the invention comprises the steps of:
Providing a workpiece on a workpiece holder at a vacuum pressure,
thereafter enclosing the workpiece in a pocket which encloses the workpiece in a closely spaced manner at the vacuum pressure,
subsequently, pressurizing the volume containing the workpiece in the pocket with a gas to a first pressure which is higher than the vacuum pressure,
cooling or heating the pocket before and/or during the enclosing and the pressurising step and thus effecting heating or cooling the workpiece in the pressurized volume of the pocket,
establishing or maintaining in an enclosure volume surrounding the pocket a second pressure lower than the first pressure,
at least one of before and of after enclosing the workpiece in the pocket, widely opening the pocket towards the enclosure volume, which is selected to be substantially larger than the volume of the pocket.

In one variant of the method according to the invention, gas is pumped from the enclosure volume at least one of before the addressed enclosing, and of during this enclosing and of after the addressed wide opening.

In a variant of the method according to the invention the volume which contains the workpiece is pressurised with He to at least 10 mbar (1000 Pa).

In one variant of the method according to the invention, the step of wide opening the pocket comprises separating two parts of the pocket through the volume of the pocket which contains the workpiece.

Heating or cooling comprises heating or cooling of at least one of the addressed parts.

In a further variant, just one of the addressed parts is heated or cooled. Thereby, and in a variant the thermal mass of the addressed one part, which is heated or cooled, is selected to be substantially smaller than the thermal mass of the other part.

In a further variant, the addressed one part which is heated or cooled is thermally coupled to the enclosure substantially less than to the other part of the pocket during heating or cooling of the workpiece.

In a further variant of the method according to the invention wide opening comprises separating two parts of the pocket through the volume of the pocket containing the workpiece, the workpiece is held substantially closer to at least one of the parts of the pocket during heating or cooling than after wide opening of the pocket. The at least one part as addressed is selected, in a variant, to be a part with a relatively high thermal mass.

In a further variant of the method according to the invention the enclosure is heated or cooled, preferably cooled.

In a variant of the method according to the invention, the method is established for manufacturing at least one degassed workpiece.

In a further variant of the method according to the invention, the method is established for manufacturing at least one thermally treated substrate.

Any number of variants of the method according to the present invention, which were described, may be combined with the exception of variants, which are contradictory.

### Solution According to the Invention for Degassing

As already addressed, all heat assisted degassing processes bear one conflicting principle: Heating up a substrate is most efficient, if the source of heat is spatially closely related to the substrate to be heated. The outgassing step is effected most efficiently if the substrate is surrounded by generous space—low pumping profiles lower the efficiency of gas removal considerably.

The present invention addresses an apparatus and process to avoid those disadvantages and at the same time allowing for a compact design of a degasser.

The invention shall now further be exemplified with help of figures. The figures show:

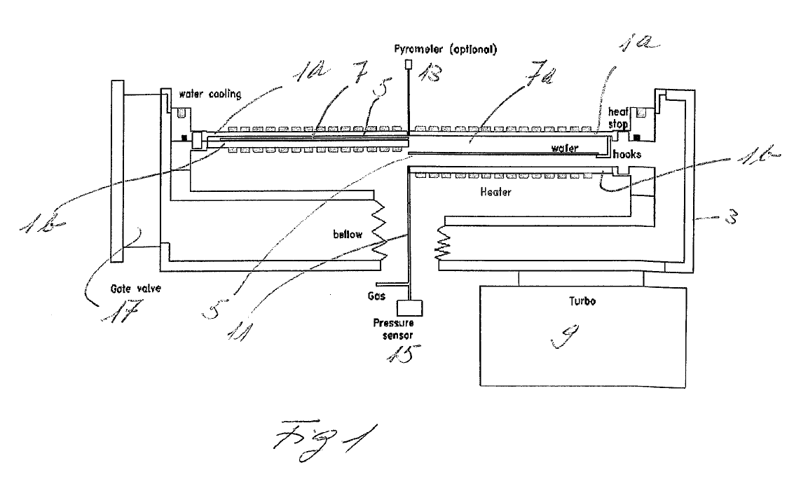

FIG. 1 schematically and simplified an embodiment of the chamber in a split display, showing the chamber in two positions, and of the apparatus according to the invention, especially for workpiece-degassing, substantially according to an actual realisation.

FIG. 2 the dependences of gas related heat transfer versus pressure in a 1 mm gas gap for two gases, namely Ar and He.

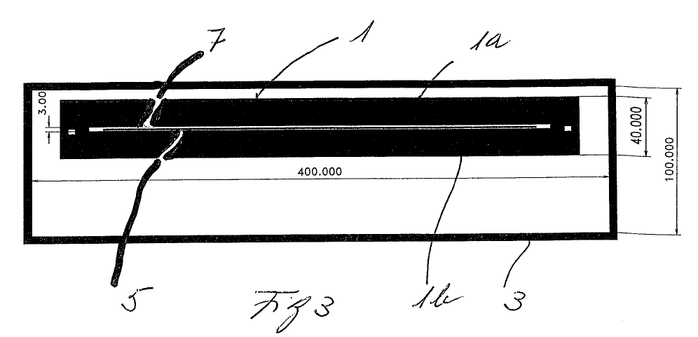

FIG. 3 schematically and simplified, an example of a degasser design according to the invention and operating the method according to the invention in a first, closed, position,

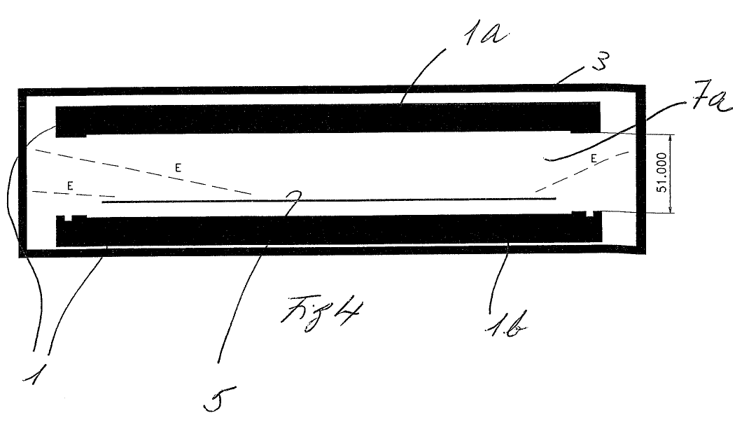

FIG. 4 the degasser of FIG. 3 in a second, opened, position.

### DETAILED DESCRIPTION OF THE INVENTION

FIGS. 3 and 4 show an example of a degasser design according to the invention with closed and opened inner chamber or pocket 1. The degasser comprises an outer housing 3 with an inner, heatable pocket 1 for the substrate 5 to be treated. The inner enclosure, the pocket 1, is designed like a clam with an upper 1a and a lower 1b shell which can be separated or closed as shown in FIGS. 3 and 4. The clam or pocket 1 is optimized to receive and support a substrate 5, such as a wafer or a composite substrate (fan-out substrate) with only little surrounding space when in closed state. The lower shell 1b may exhibit pins, ball-shaped supports or a contoured surface with means to support a substrate to be treated.

The upper 1a or the lower 1b shell may be fixedly mounted to the outer housing 3, thus leaving only the other shell as movable part. Of course one may realize the degasser according to the invention also as a clam, i.e. pocket 1, with both shells 1a, 1b, as parts of the pocket 1, being movable.

Upper and/or lower shell 1a, 1b shall include means for introducing a working gas such as Ar, N₂ or He into the gap to enhance the heat transfer.

When closed, the upper and lower shells 1a, 1b envelop a certain volume. The contact area of upper and lower shell 1a, 1b may be sealed, e.g. by a Viton O-ring. Alternatively the edges where upper and lower shells 1a, 1b meet may be construed to be not thoroughly gas tight—they allow a certain amount of gas to evade from the gap formed by the clam. Depending on the type of substrates 5 to be treated, one may foresee even additional openings like feedthroughs to allow more leaking of gas. It has to be noted that a flush of gas is not the goal of these leaks, since the thermal transport is accomplished by the gas remaining in the volume. However, outgassing molecules and excess gas may have a defined path to evade. The man skilled in the art will in this case limit the supply of gas to the lowest possible flow needed.

The shells 1a, 1b are being machined from a material with good thermal capacity and/or conductance so they can buffer and/or transfer heat. They may both be heated e.g. electrically, preferably constantly so the shells 1a, 1b allow to rapidly release heat to a substrate 5 freshly inserted into the clam, i.e. pocket 1. Access ports for the substrate to be degassed and pump exhausts are not shown in FIGS. 3 and 4.

In a preferred embodiment the upper shell 1a will not be actively heated but exhibit a large thermal mass. Preferably this will be the one fixedly mounted to the top of the outer enclosure 3 via insulating posts. The large thermal mass will provide a reservoir of heat for any freshly inserted substrate 5 and will at the same time absorb any excess heat provided by the lower, heated shell 1b. After opening the clam, i.e. pocket 1, and thus separating the clam, the upper, hot shell 1a will be far more distant than before and thus immediately be less actively heating the substrate 5 as before. If it is the goal of allowing a rapid heat-up AND cool down, one may choose a material with low thermal mass for the lower (heated) shell 1b thus supporting the cool down as soon as the clam 1 is being opened. A man skilled in the art will add heat reflectors or shields as appropriate or necessary for the processes to be performed.

An inventive heat-up and degas process will comprise at least the following steps:
1) Opening the inner enclosure in the outer housing to accept a substrate
2) Inserting a substrate into the degasser, e.g. by means of a handler or a robot with appropriate transporting means (gripper, fork,
3) Placing the substrate on the lower part of the clam (lower shell) or moving the lower shell upwards so as to lift the substrate of the handler.
4) Removing the handler from the clam
5) Closing the shell.
6) Introducing the working gas for heat transfer.
7) As soon as the substrate has reached the desired temperature the clam is being opened
8) The outgassing molecules evade into the outer housing and thus can be pumped away very effectively via the enlarged pumping profile/pumping cross-section.

Heating the upper and lower shell 1a, 1b can be accomplished by a constant feed of power to the clam, the heat dissipating to the substrate 5 will be supplied during the load/unload times of a substrate and/or idle times. It goes without saying that applying a power profile with enhanced heating during actual operation is also possible. The man skilled in the art will realize this according to the need of the substrate to be heated.

An actual embodiment of the invention could looks like that:

The inner chamber 7 (gap of the clam) has a height of 3 mm and a diameter of 320 mm. Its volume is 241 cm³ without the Si wafer (substrate). The outer chamber 3 with an inner height of 100 mm and a diameter of 400 mm has, after subtracting the outer dimensions of the inner chamber (40 mm height, diameter 360 mm) a volume of 8494 cm³. By opening the inner chamber 1 the gas which has been used to fill up the inner chamber is expanding to a volume, which is 35 times higher. This pressure burst can easily be taken up by the high vacuum pumps connected to the outer chamber.

Material which has to be outgassed from the substrate can be pumped out easily if a wide gap 7a is provided as shown in FIG. 4 with 51 mm. In high vacuum the outgassing material is in the molecular flow regime and follows the path of direct sight, as indicated by the dotted lines E in FIG. 4. The substrate 5 will also cool down due to radiation to the water-cooled walls of the outer chamber 3. This additional effect, also indicated by the dotted lines E in FIG. 4, is wanted and also requires a wide open gap 7a of the inner chamber, i.e. pocket 1.

FIG. 1 shows an embodiment closer to the actual realization in a split-display. The left part of the figure addresses the “closed clam” state where the vacuum pump 9 (“turbo”) is acting mainly on the volume of the outer housing 3 while the gas is being fed—11—via the lower shell 1b. A pressure sensor 15 may allow controlling the actual pressure inside the clam's gap 7, 7a. A pyrometer 13 can be installed to control the temperature of the substrate 5. FIG. 1 shows the substrate being placed on hooks inside the clam. The left side of FIG. 1 mentions a gate valve 17 establishing a sealable interface to further enclosure which will house an outside handler usable for the load/unload of substrates.

FIG. 2 shows the dependencies of the gas related heat transfer vs. pressure in a 1 mm gas gap for two gases such as Ar and He. One can learn that increasing the Ar pressure in such a 1 mm gap from 100 to 1000 Pa will not considerably enhance the heat transfer. Using He instead of Ar will allow to have a heat transfer at least 3× higher at 100 Pa and even more than 6× higher at 1000 Pa.

The degasser can be used also as a pure heating station, since the inventive clam inside an outer enclosure will also serve its purpose with a non-degassing substrate. In reverse the same structure can provide heat transfer in the other direction, as a cooling station, where a substrate can be effectively cooled in a clam within a larger enclosure.

For both pure heating and pure cooling as well as degassing embodiments is valid that the small volume useful for gas-related heat transfer in the gap of the clam is being mechanically expanded to a larger volume allowing for quick removal of the working gases. Whether additional outgassing material is part of the removed gases, is relevant only for the time the substrate remains in the opened lower shell after the heat transfer treatment. The criterion for the transport to a next process station will be the residual pressure in the outer housing and/or the temperature of the substrate.

### TECHNICAL FEATURES IN SUMMARY

A degasser setup including:

1. A pocket (clam) to accept a substrate inside a vacuum enclosure.

2. A minimal volume inside this clam surrounding the substrate to enable a fast gas fill and a fast pump out.

3. The substrate is placed in the middle of top and bottom plates (shells) of the clam.

4. The substrate is placed on 3 balls in the bottom plate to minimize the contact of the substrate to the plate and to allow its relaxation during heat-up

5. The clam comprises a heated bottom plate (lower shell) with a 2-zone heater

6. Thermally decoupling the heated bottom plate from a base plate to thermally decouple it from the chamber.

7. The clam having optionally an unheated top plate, which has a certain thermal mass to store heat, but is otherwise decoupled thermally from the chamber

8. The clam being able to be opened up to at least 50 mm to enable a high pumping speed for outgassing material.

9. The volume of the outer chamber being at least 10 times higher than the volume of the inner chamber, preferably >30 or even >35 times higher

10. The walls of the outer chamber being water-cooled and directed towards the substrate to enable heat exchange by radiation

11. The setup can be used in almost the same design as a cooler, where the heater plate in the bottom plate is replaced by a water-cooled plate.

A method to use a clam degasser according to the invention:

1. The top plate is heated up in clam closed position preferably filled with He up to 10 mbar (1000 Pa), during conditioning of the module

2. The degas process consists of 2 steps:

3. Heat up with closed clam

4. Degas with open clam

5. For the heat up the clam is filled with gas up to 10 mbar, preferably with He

For the degassing step the clam is opened as much as possible providing a very direct path of the outgassing material to the pumps.

1. A heater and/or cooler vacuum chamber, for at least one workpiece, preferably a single workpiece, especially a degasser chamber, comprising:
an enclosure enclosing an enclosure volume;
within said enclosure volume, a controllably heatable and/or coolable pocket enclosing a pocket volume;
a workpiece holder in said pocket volume
a gas feedline discharging in said pocket volume
a port from the surrounding of said enclosure into said enclosure volume;
wherein:
a) the inner surface of said pocket is tailored to surround said workpiece applied on said workpiece holder in a closely spaced manner, distant from said workpiece
b) said pocket comprises a controllably closable and openable gas flow connection from the pocket volume into the remainder said enclosure volume, said gas flow connection representing, in open state, a negligible gas flow restriction.

2. The chamber of claim 1 wherein said pocket comprises two mutually controllably joinable and separable parts, separated through said pocket volume.

3. The chamber of claim 2 for a plate shaped workpiece, wherein said parts are separable perpendicularly to the extended surfaces of said plate shaped workpiece on said workpiece holder, preferably adjacent the periphery of said plate shaped workpiece.

4. The chamber of claim 2 only one of said parts comprising a heater and/or cooler, preferably a two-zone heater.

5. The chamber of claim 4 wherein said one part has a thermal mass which is substantially smaller than the thermal mass of the other part of said two parts.

6. The chamber of claim 2 wherein said workpiece on said workpiece holder is more distant from at least one of said parts, preferably from both of said parts, in open state of said pocket than in closed state.

7. The chamber of claim 1 wherein said pocket is substantially thermally decoupled from said enclosure.

8. The chamber of claim 2 wherein one part of said pocket is a part of the wall of said enclosure.

9. The chamber of claim 2 wherein the parts are separable by at least 50 mm.

10. The chamber of claim 1 wherein a ratio of the enclosure volume to the pocket volume is at least 10, preferably at least 30, preferably at least 35.

11. The chamber of claim 1 wherein said enclosure comprises cooling means and/or heating means for said enclosure volume, preferably a water cooling and/or heating arrangement.

12. The chamber of claim 2 wherein at least one part of the pocket is movably linked to said enclosure by means of a bellow, said gas feed line being arranged within said bellow, towards and into said pocket volume.

13. A heater and/or cooler apparatus comprising a chamber according to claim 1 and comprising a gas reservoir operationally connected to said gas feed line and preferably containing at least one of Ar, N₂, He.

14. The apparatus of claim 13 comprising a vacuum pump operationally connected to said port of said chamber.

15. A method of manufacturing at least one heated or cooled workpiece, especially of a single workpiece, especially of at least one degassed workpiece, comprising the steps of:
providing a workpiece on a workpiece holder at a vacuum pressure
enclosing said workpiece on said workpiece holder in a pocket and in a closely spaced manner at said vacuum pressure
pressurizing the volume containing said workpiece in said pocket with a gas to a first pressure higher than said vacuum pressure;
heating or cooling said pocket before and/or during said enclosing and said pressurizing step
establishing or maintaining in an enclosure volume surrounding said pocket a second pressure substantially lower than said first pressure
wide opening said pocket towards said enclosure volume at least one of before and of after said enclosing, said enclosure volume being substantially larger than said volume of said pocket containing said workpiece and as pressurized.

16. The method of claim 15 comprising pumping gas from said enclosure volume at least one of before said enclosing, of during said enclosing and of after said wide opening.

17. The method of claim 15 comprising pressurizing said volume with He to at least 10 mbar (1000 Pa).

18. The method of claim 15, said wide opening comprising separating two parts of said pocket through said volume of said pocked containing said workpiece, said heating or cooling comprising preferably heating or cooling of at least the one of said parts, preferably of just one of said parts, and preferably selecting the thermal mass of said one part substantially smaller than the thermal mass of the other of said parts, and, preferably, thermally coupling said one part substantially less to said enclosure than to the other of said parts during said heating or cooling, and, preferably, maintaining said workpiece substantially closer to the one of said parts during said heating or cooling than after wide opening.

19. The method of claim 15 said enclosure being heated or cooled, preferably cooled.

20. The method of claim 15 for manufacturing at least one degassed workpiece.

21. The method of claim 15 for manufacturing at least one thermally treated substrate.
